(19) United States
(12) Patent Application Publication
(10) Pub. No.: US 2021/0362999 A1
(43) Pub. Date: Nov. 25, 2021

(54) SURFACE MICROSTRUCTURES

(71) Applicant: Andrew Richard PARKER, Richmond Greater London (GB)

(72) Inventor: Andrew Richard PARKER, Richmond Greater London (GB)

(21) Appl. No.: 16/640,375

(22) PCT Filed: Aug. 24, 2018
(86) PCT No.: PCT/GB2018/052410

§ 371 Date: Feb. 20, 2020

(30) Foreign Application Priority Data
Aug. 24, 2017 (GB) 1713629.2

(51) Int. Cl. B81B 3/00; B08B 17/06; B29C 59/02

(52) U.S. Cl. CPC B81B 3/001; B29C 2059/023; B29C 59/022; B08B 17/065

(57) ABSTRACT

A method of manufacturing and a surface microstructure that includes a surface; and a plurality of protrusions on the surface, where each of the protrusions has a width that changes along its length, where the protrusions are all oriented in substantially the same direction; and where the protrusions each have a length between 10 and 1000 μm and a maximum width between 5 and 100 μm.

The invention relates to a surface microstructure, in particular, but not exclusively, to a surface microstructure which is self-cleaning such as mud and/or water shedding. The surface microstructure may offer further properties such as anti-microbe, anti-fouling and/or super hydrophobic properties.

There is an increasing interest in the field of self-cleaning materials. It is known to use self-cleaning coatings on glass. These coatings are generally either hydrophobic or hydrophilic. These types of coating may clean themselves in wet conditions; in the case of hydrophobic material by rolling droplets and in the case of hydrophilic material by sheeting water that carries away dirt.

It is desired to provide novel surface microstructures which have self-cleaning properties.

WO 2015/170120 discloses a surface microstructure with protrusions that each have a length between 0.25 and 100 μm and a width between 0.1 and 1.5 μm.

It is desirable to provide a surface that has self-cleaning properties and that is economically viable to make on a commercial scale.

In a first aspect, the present invention provides a surface microstructure, the surface microstructure comprising: a surface; and a plurality of protrusions on the surface, wherein each of the protrusions has a width that changes along its length, wherein the protrusions are all oriented in substantially the same direction; and wherein the protrusions each have a length between 10 and 1000 μm and a maximum width between 5 and 100 μm.

In a second aspect, the present invention provides a method of manufacturing a surface microstructure, the method comprising: providing a surface; and providing a plurality of protrusions on the surface, wherein each of the protrusions has a width that changes along its length, wherein the protrusions are all oriented in substantially the same direction; and wherein the protrusions each have a length between 10 and 1000 μm and a maximum width between 5 and 100 μm.

It has been surprisingly realised that the advantageous properties such as self-cleaning (e.g. mud and/or water shedding) may be achieved with surface structures that is larger than that disclosed in WO 2015/170120. The larger structures may be easier to manufacture and thus it may be possible to manufacture them on a commercial scale in an economically viable manner.

In a broadest aspect, the present invention provides a surface microstructure, the surface microstructure comprising: a surface; and a plurality of protrusions on the surface.

In another aspect, the present invention may provide a method of manufacturing a surface microstructure, the method comprising: providing a surface; and providing a plurality of protrusions on the surface.

Each of the above aspects may comprise one or more of the following features.

The surface microstructure may have advantageous self-cleaning properties. The surface microstructure may be for forming a self-cleaning surface. The surface microstructure may be a self-cleaning surface microstructure. In particular, the microstructure may promote mud-shedding, e.g. in damp conditions, and/or water shedding. This means that dirt may fall away from the surface, be easily knocked off, or be easily washed off. Additionally and/or alternatively, the surface may be an anti-microbe and/or anti-fouling surface (i.e. have a tendency to expel living things, or to prevent multi-celled bodies from being able to attach to the surface). Additionally or alternatively, the surface microstructure may be super-hydrophobic.

The self-cleaning properties may be achieved due to the shape and/or relief of the microstructure, i.e. the shape of the protrusions. Thus, it may be the microstructure itself that causes self-cleaning, mud shedding and/or water shedding etc that gives the advantages rather than the particular material that is used.

The self-cleaning (e.g. mud shedding and/or water shedding) properties of the microstructure may be improved compared to the same surface (e.g. same material) but without the surface microstructure.

The surface may be a man-made surface and the protrusions may be formed on or from the man-made surface. The surface microstructure may be an artificial and/or an industrially prepared structure.

The surface may be the outer or upper surface of a substrate, for example, provided on a sheet of material.

The protrusions may be formed by cutting grooves into the surface to form the protrusions.

The surface may a fiber. In this case, the protrusions may be formed by cutting grooves into the surface of the fibre to form the protrusions.

The surface microstructure may be applied to articles or objects in which it is desirable to have such self-cleaning and/or super-hydrophobic properties.

The surface microstructure according to the present invention may be used on a number of different articles. A non-exhaustive list includes apparel or garments including clothing (e.g., outdoor clothing, protective clothing, etc) and footwear, including the sole of the footwear, such as boots and sports shoes.

As an example, the surface microstructure may be used on the sides or the sole of a sport shoe, such as a trainer, running shoe, football boot, rugby boot, etc., or other footwear that are likely to be used in muddy conditions. With this example, the microstructure can act to help keep the shoe looking clean, even after use in muddy environments.

The surface microstructure may be provided on a surface of an article. Such an article may have self-cleaning, mud shedding, water shedding, anti-microbe, anti-fouling and/or super hydrophobic properties.

When the surface microstructure is designed for mud shedding, it may be borne in mind that mud is soil and water. The soil may be a combination of sand, silt and clay, and different combinations of these constituents will lead to the different types of soil and thus different types of mud and thus different requirements of the mud-shedding structures. Thus the exact size, shape and material etc of the microstructure may need to be optimised depending on the application of the structures and what they are expected to come into contact with.

The protrusions being oriented in substantially the same direction may mean that the longitudinal axis (i.e. the axis along the length of the protrusion that may be parallel to the surface) is within 20°, 10°, 5° or 1° of the axis of each of the other protrusions. The protrusions may extend in a length wise direction in substantially the same direction. The protrusions may extend in a direction along the surface of the substrate in a direction that is substantially parallel to the other protrusions.

One or more or each of the protrusions may be elongate. For example, each protrusion may have a length that is at least twice the maximum width of the protrusion.

The protrusions may be elongate in a dimension (i.e. the length) that is substantially parallel to the plane of the surface.

The length direction may be the greatest dimension of one or more or each protrusion. For example, the length of each protrusion may be greater than its width and its height.

The length dimension and/or the width dimension may be substantially parallel to the plane of the surface. The height dimension may be substantially perpendicular to the plane of the surface.

Each protrusion may have a length to maximum width ratio of between 1:0.05 and 1:0.7. Preferably the length to width ratio is between 1:0.08 and 1:0.33, preferably about 1:0.2.

The height (h) of each protrusion may be at least 5 μm, 10 μm or 15 μm. The height of each protrusion may be between 5 μm and 500 μm, between 5 and 150 μm, or between 15 and 75 μm. The height may be the distance from the surface to a point of the protrusion furthest from the surface.

The protrusions may each have a width which varies along its length. For example, the protrusion may decrease in width along its length. The width of the protrusion may decrease to a point at one end of the protrusion.

One or more or each protrusion may have a width that is maximum at one end and minimum at the other opposite end of the protrusion. The width of the protrusion may decrease constantly and/or linearly along the length of the protrusion. The widest end of the protrusion may be referred to as its base end and the narrowest end of the protrusion may be referred to as its tip end.

The maximum width (w) of each protrusion may be between 5 μm to 100 μm, 5 μm to 50 μm, or 9 to 45 μm.

The length (l) of each protrusion may be between 10 and 1000 μm, 100 to 500 μm, 45 μm to 225 μm or 100 to 500 μm. The length may be greater than 100 μm.

Each protrusion may be triangular. For example, when viewed in plan view, and/or in cross section in a plane parallel to the plane of the surface, each protrusion may have a triangular shape.

The protrusions may each have a rounded outer surface and/or one or more rounded edges.

One, or more, or each protrusion may be connected to the surface along its entire length. Thus, there may be no gap and/or separation between the protrusion and the surface. One or more or each protrusion may be fixed to and/or integral with the surface along its entire length. This arrangement may make manufacture easier compared to an arrangement in which the protrusions are not connected to the surface along its entire length.

The protrusions may only be connected to the surface for a portion of the length, for example at one end only. There may be a gap and/or no connection between a portion of the length of the protrusion and the underlying surface. The protrusion may thus have a fixed end and a free end that can move relative to the surface. Such an arrangement may increase the hydrophobicity of the structure.

However, it may be more difficult to manufacture.

One, or more, or each protrusion may have vertical sides. These sides may be connected/attached to the surface.

The protrusions may all extend in substantially the same direction.

The protrusions may each have substantially the same dimensions.

The protrusions may all be substantially identical. For example, the protrusions may all be identical within manufacturing tolerances. This means that the surface microstructure may have uniform self-cleaning or other properties across the entire area that the protrusions are provided. The properties of the microstructure may be directional. The directional properties may be dependent on the orientation of the protrusions. The surface microstructure may have better mud shedding and/or water shedding properties in a direction that is parallel to the length of the protrusions compared to a direction that is perpendicular to the length of the protrusions.

The protrusions may be provided in an ordered manner. The plurality of protrusions may be an array of protrusions. For example, the protrusions may be provided in a plurality of rows when viewed in plan view. When the protrusions are provided in a plurality of rows, the rows may be parallel to each other.

The distance between each protrusion may be between 1 and 200 μm, 1 and 100 μm, 9 and 90 μm, or 9 and 45 μm.

The distance between adjacent protrusions may vary along the length of each of the adjacent protrusions.

The distance between each protrusion at its base end may be between 1 and 100 μm, 1 and 50 μm or 9 and 45 μm. This may be referred to as the base separation (bs). The base separation may be the same or substantially the same as, such as within 5% of, the width of the protrusions.

The distance between each protrusion at its tip end may be between 1 and 200 μm, 10 and 100 μm or 18 and 90 μm. This may be referred to as the tip separation (ts).

The rows may be separated by a gap between 1 to 100 μm, 1 and 50 μm, 1 and 25 μm, 3 and 15 μm, i.e. the distance between the end of the protrusions in one row and the start of the protrusions in the next row may be 1 and 50 μm, 1 and 25 μm, 3 and 15 μm. This may be referred to as the row separation (rs).

Alternatively, the end of the protrusions in one row may overlap the start of a protrusion in the next row. The protrusions in one row may be laterally offset from the protrusions in the next row. For example, the tip of the protrusions in one row may be in a lateral direction between the two base ends of the protrusions in the next row.

The surface microstructure may be provided on a region of an article. The article may also have one or more other regions with other surface microstructures. The other surface microstructures may have different dimensions, shapes, orientations, materials etc and thus have different properties. Thus the article may have a first region of the surface having one property and at least a second region offering a second different property.

The surface microstructure may be hydrophobic and/or hydrophilic. The surface microstructure may be formed from and/or coated with a material that is hydrophobic and/or a material that is hydrophilic.

The surface microstructure may comprise regions that are hydrophobic and/or regions that are hydrophilic.

For example, the protrusions could be formed from and/or coated in a material that hydrophobic or hydrophilic and/or the surface may be formed from and/or coated with a material that is hydrophobic or hydrophilic. The protrusions may be hydrophobic whilst the protrusions may be hydrophilic or vice versa. The surface microstructure may enhance hydrophobicity or hydrophilicity when made in material of that type.

The surface microstructure may cause improved and/or faster water shedding and this may be used in applications where this is desirable such as in sandals/shoes used for water-sports, or on a beach.

The protrusions may also aid hydrodynamics. The microstructure may be on articles such as swimming costumes or the hull of a ship. The microstructure may reduce friction on ship hulls or swimming costumes. The microstructure may be used to prevent growth of marine organisms on objects such as the hull of a ship.

The protrusions may be added to the fibres of a fabric. This may be achieved by making angled cuts into the surface of a fibre. The cut may be angled relative to the longitudinal axis of the fibre. These cuts may be at regular intervals and/or all in the same direction along the length of the fibre and/or around the circumference of the fibre. The cuts may result in V-shaped protrusions being formed on the surface of the fibre. Such fibres with the protrusions formed thereon may be used to form a fabric.

The outer surface of the protrusions may be smooth.

The microstructure and/or protrusions may include a coating of a hydrophobic material, such as a wax or oil. The microstructure and/or protrusions may be coated with FDTS (Perfluorodecyltrichlorosilane). This may be evaporated chemical FDTS.

The surface microstructure may comprise a thin coating with a wax or other hydrophobic material onto a solid structure (such as a pre-form etc.).

The protrusions may be formed from a polymer or plastics material such as polyethylene terephthalate (PET), polyamide, polytetrafluoroethylene (PTFE), polystyrene, polyurethane, polyolefin, polycarbonate, polyvinyl chloride, rubber, silicone rubber, and/or pseudo-leather (e.g. poly urethane) etc. The protrusions may be formed from a hard polymer such as those typically used for shoe soles (such as sports and deck shoes) or polymers that are typically used to make moulded boat hulls.

Alternatively the protrusions may be formed from other materials such as glass or metal and/or paint, varnish or lacquer. The material from which the protrusions are formed may be a natural material or a man-made material. The material used to form the protrusions will depend on factors such as the application, the manufacturing method etc. Dirt particles can also be relatively abrasive, and accordingly, preferably the material of the protrusion is chosen with this in mind in order to provide a hard wearing, mud shedding surface for the article of clothing or, more preferably, item of footwear such as a sports shoe, in locations where dirt is likely to collect.

The material of the protrusions may be different to that of the surface. This may mean that there is a material difference between the surface of the protrusions and the surface of the surface between them. The properties of the surface and the protrusions may be different.

For example, if the protrusions are printed, the printed material, e.g. “ink”, may be a different material to the surface on which it is printed. If the protrusions are engraved (e.g. etched) or stamped, a thin (e.g. 10 micron) film may be deposited on the substrate first, and then removed between the protrusions to reveal the (different) material beneath.

The surface to which the surface microstructure is applied may be a continuous flat surface such as the surface of an article such as a trainer. By flat surface it is meant that the surface is flat at a local level to the protrusion, i.e. the surface may be flat within 1000 μm of the protrusion. On a macro scale the surface may not be completely flat, e.g. it may be curved. The surface may be relatively smooth. Alternatively, the surface may be a fibre. In this case the fibre with protrusions thereon may be used to form an article, such as clothing which comprises the surface microstructure.

When viewing the surface microstructure from above, over 25% of the surface may be covered by the protrusions, or greater than 50% or up to 75%. For example the raised protrusions may cover 25% to 75% of the surface of the structure, or about 50%. Preferably there are gaps between the protrusions and these may represent 25% or more of the area of the surface. The surface between protrusions may cover 25% to 75% of the surface area. This may be equal to 100% minus the area covered by the raised protrusions.

The surface and the protrusions may be formed from the same material. The protrusions may be integral with the surface or may be a separate component which is joined to the surface, such as by adhesive or welding.

The surface microstructure may be formed by any suitable method. For example, the protrusions may be stamped out of the surface (e.g. using a stamp applied to the surface to form the protrusions). The protrusions may be formed by etching into the surface or by using a process that removes material between the protrusions.

The surface microstructure may be formed by depositing a material onto the surface to form the protrusions. For example, the protrusions may be made using printing such as 3D-printing.

It has been found that the protrusions of this invention are suitable for volume manufacture using standard machines, such as using moulds.

A negative of the microstructure may be formed around a cylindrical body, for example either by directly forming it thereon or forming it on a flat surface that is wrapped around the cylindrical body so as to create a cylindrical mould. The cylindrical mould may be rolled over an impressionable surface on which it is desired to form the microstructure. This may for example be a polyurethane sheet or the surface of a solar panel.

The surface microstructure may be formed through a self-assembly technique. For example, a material may be applied to the surface, or the surface may comprise a material, which forms or coalesces to form the protrusions.

This may be achieved through self-assembly in a drying liquid such as paint, varnish or lacquer. The liquid may be a viscous liquid. Drops, i.e. protrusions, may form as the liquid dries. This may be caused by the liquid slowly running down the surface as it dries. This may be due to gravity. As the liquid dries, the surface may be oriented so that it has a component that is at least parallel to the direction of gravity.

As the liquid runs down the surface the tip of the drops (i.e. protrusions) may become increasingly smaller until the drops halt. The wake of each drop may take the form of a raised, elongated Isosceles triangle.

The liquid may be encouraged and/or manipulated to self-form the protrusions by including structures into the liquid (e.g. microspheres), where each structure causes one drop/protrusion.

The liquid may form the drops by reaction-diffusion. This may be achieved by a mixture of two (or more) chemicals in a mixture self-organising/orienting beyond external forces. This self-organising and/or orienting may be so that they come to a state of chemical equilibrium in the patterns that they form. The proportion of a first chemical to a second chemical in the mixture may determine the self-assembled shapes.

The protrusions may be in a random pattern rather than for example in rows.

The surface microstructure may be formed by moulding.

This method of manufacture may create protrusions on a solid surface. An inverse of the protrusions may be housed on moulds. These may for example be moulds for large, more complex structures like the soles of running shoes or football boots, or wellington boots, or the mud-flaps of cars.

For a studded item of footwear (such as a football boot or a rugby boot) the studs may be provided as separate components that are affixed, such as screwed in) to the sole during or after manufacture. This may allow the sole of the footwear and the separate studs to be formed, e.g. moulded, with the protrusions separately. This may ease manufacture. For example the relatively flat sole of the footwear may be formed, e.g. moulded, to have the microstructure thereon or have a microstructured surface applied thereto. Separately the studs may be formed, e.g. moulded, to have the microstructure thereon or have a microstructured surface applied thereto (such as wrapped around). Once the sole and studs have been separately formed (e.g. by moulding or any other appropriate manufacturing method) with the microstructure thereon the studs may be affixed to the sole such as by screws.

Such a manufacturing method may be used for other complex shaped parts. Specifically parts may be separately provided with a microstructured surface before being affixed together.

The method may comprise applying the surface microstructure to an article, such as an item of clothing or an item of footwear.

The method may comprise stamping the protrusions out of the surface. The method may comprise depositing a material onto the surface to form the protrusions. The method may comprise moulding the protrusions.

The surface microstructure may be directly on the surface of the article (the article itself is processed to include the surface microstructure) or it may be on a material applied to the surface of the article.

The present invention can be used in a large number of applications.

Examples include shoes, including the sole of shoes, such as trainers, deck shoes, wellington boots, hiking boots, snowboard boots, ski boots, football, rugby, or American football boots etc., clothing such as coats, protective garments, overalls, contamination suits, sportswear, swim suits, military, services, medical or other uniforms, yachting clothing etc., articles such as skis, snowboards, sledges, tyres, tents, garden buildings, garden furniture, carpets, upholstery, furniture, rucksacks, sleeping bags, umbrellas, walls, roofs, flooring, outdoor staging, contact lenses, medical equipment, etc., parts of vehicles such as aeroplanes, cars, vans, trucks, construction machinery, farm machinery, boats, bicycles, hovercrafts etc., engine parts, oil/petrochemical applications such as oil pipes, oil/petrochemical machines or devices, etc., solar panels and any other application in which a self-cleaning, mud shedding, water shedding, anti-microbe, anti-fouling and/or a super-hydrophobic surface may be of benefit.

For example, the microstructure may be on the inner tread of a vehicle tyre. This may allow the tyre to have the advantageous microstructure thereon without the microstructure being on a part of the tyre that will be abraded by a road.

The surface microstructure may be coated with a reflector in the manner described in WO2016/156863 so as to provide a structural colour to the surface micro structure. The protrusions may act as profile elements that deform the reflector.

The reflector may have the property that when flat the colour of light observed will depend on the viewing angle. This property of colour change with changing viewing angle may be reduced and effectively removed over at least a range of viewing angles by distorting the multilayer reflector using the protrusions of the surface microstructure. This is because the underlying protrusions cause the reflector to vary in angle relative to the plane of the surface (as the reflector follows the profile of the protrusions). Consequently over a broader range of viewing angles, a significant proportion of the reflector producing the observed reflections will be orientated more to the observer in a way that also substantially maintains a more constant orientation, i.e. the normal position. As a result, the colour observed by the eye over that broader range of angles is relatively constant.

The reflector may be any reflector that imparts a colour.

The reflector may be a multilayer reflector, such as a quarter wave stack reflector.

The reflector may be significantly thinner than the dimensions of the protrusions such that it can conform substantially to the profile of the protrusions. As a result, the reflector may have no or negligible effect on the self-cleaning properties of the underlying surface microstructure. Such a structure combining a surface microstructure with protrusions with the reflector may be a dual, mud shedding and structural colour device.

A film with this dual function may be provided. This may be a polymer film. This may be a film that can be attached to an object. This may be achieved by wrapping, i.e. the film may be a wrap film.

Attaching such a film to an object may impart the self-cleaning and/or structural colour to the object. This may be used for applications such as cars, signs (such as road/airport/port signs), advertising boards and military applications etc. Dirt and mud on the surface of the microstructure may block the observer from being able to see the colour. Thus, the self-cleaning aspect created by the protrusions may be useful.

The microstructure may be applied on surfaces where colour is particularly important and should be kept dirt free. For example, the microstructure may be applied to the top of a coloured surface (e.g. coloured by pigments and/or structural colour as in WO2016/156863 for example). This may for example be on the surface of a car.

When used together with a coloured surface the microstructure disclosed herein may be provided on the uppermost layer. For example, in the case of structural colour, the present microstructure may be provided on a protective coating on top of the reflector that provides the structural colour effect.

Certain preferred embodiments of the present invention will now be described by way of example only with reference to the accompanying drawings, in which:

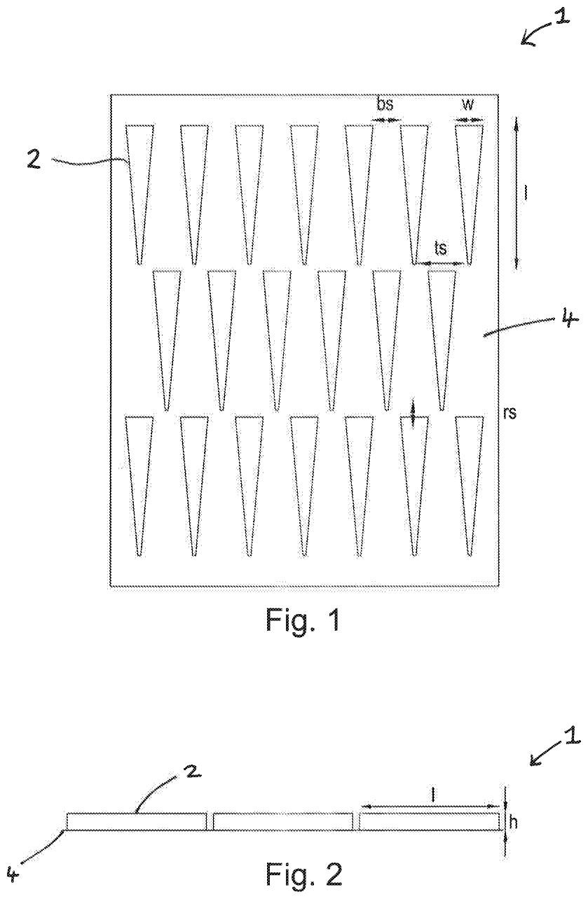

FIG. 1 shows a plan view of a surface microstructure;

FIG. 2 shows a side view of the surface microstructure;

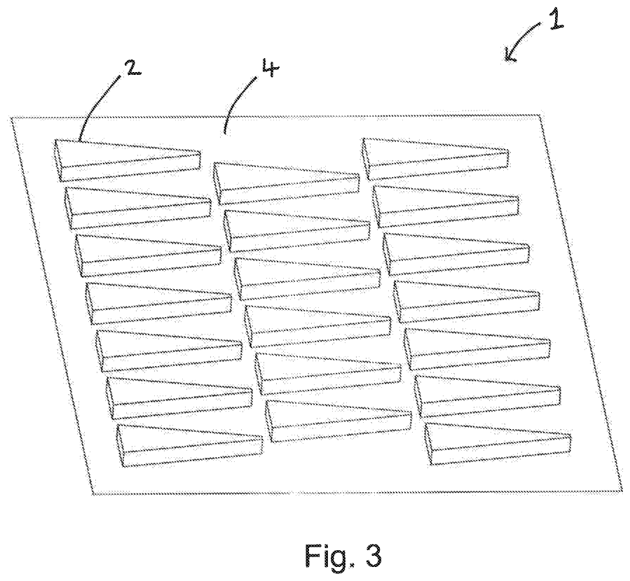

FIG. 3 shows a perspective view of the surface microstructure;

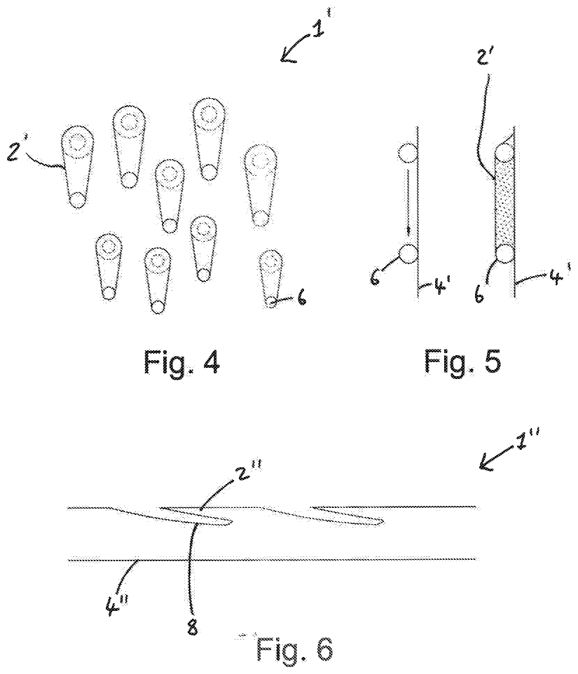

FIG. 4 shows a plan view of a self-assembling surface microstructure;

FIG. 5 shows a side view of the self-assembling surface microstructure;

and

FIG. 6 shows a side view of a surface microstructure formed in a fibre.

FIGS. 1, 2 and 3 show a surface microstructure 1 with a plurality of protrusions 2, i.e. raised elements, on a surface 4.

The protrusions 2 each decrease in width along their length and in this particular embodiment are each triangular.

The protrusions 2 are all oriented in substantially the same direction, i.e. their longitudinal axes are all substantially parallel.

The protrusions 2 each have a length (I) between 10 and 1000 μm and a maximum width (w) between 5 and 100 μm.

In this embodiment the protrusions 2 are ordered and in a number of parallel rows.

The distance between each protrusion 2 in a row may be between 1 and 200 μm. For example the distance between each protrusion 2 at its widest end (bs), i.e. its base end, may be between 1 and 100 μm.

The distance between each protrusion 2 at its narrowest end (ts), i.e. its tip end, may be between 1 and 200 μm.

The rows may be separated by a gap (rs) that is between 1 to 100 μm, i.e. the distance between the end of the protrusions 2 in one row and the start of the protrusions in the next row may be between 1 and 100 μm.

These protrusions 2 have the effect of improving the self-cleaning (e.g. mud and/or water shedding) properties of the surface compared to a surface without such protrusions but that is otherwise identical.

These protrusions 2 may be formed by any known method such as stamping, moulding, photolithography and/or 3D printing.

FIGS. 4 and 5 show a surface microstructure 1′ where the protrusions 2′ are formed from a self-assembly method.

This may be achieved through self-assembly in a drying viscous liquid such as paint, varnish or lacquer. Drops, i.e. protrusions 2′, may form as the liquid dries. This may be caused by the liquid slowly running down the surface as it dries due to gravity. As the liquid dries, the surface may be oriented so that it has a component that is at least parallel to the direction of gravity such that all of the protrusions 2′ extend in substantially the same direction.

As the liquid runs down the surface 4′ the tip of the drops (i.e. protrusions 2′) may become increasingly smaller until the drops halt. The wake of each drop takes the form of a raised, elongated isosceles triangle.

The liquid is manipulated to self-form the protrusions 2′ by including structures 6 into the liquid (e.g. microspheres), where each structure causes one drop/protrusion. The structures may be sized to cause the protrusions 2′ to each have a length between 10 and 1000 μm and a maximum width between 5 and 100 μm.

FIG. 6 shows a surface microstructure 1″ in which the protrusions 2″ are formed by cutting grooves 8 into the surface of a fibre 4″.

The surface of the microstructure 1″ in this case is a fiber 4″.

### Experimental Results

Substrates made of silicon 0.7 mm thick, <100> orientated, doping unknown were tested with regard to their mud shedding properties. The microstructures had been formed using photolithography.

A first group, the (A) group, was coated with an evaporated chemical FDTS to make them hydrophobic.

A second group, the (B) group, had no coating so had a surface SiO₂ layer which is naturally hydrophilic.

In each group (A and B) five different samples were tested (i.e. 10 samples in total). This was a smooth, i.e. microstructure-less unstructured, reference sample referred to as samples A0 and B0, and four microstructures sampled having a surface microstructure as shown in FIGS. 1, 2 and 3, wherein the first (samples A1 and B1) had triangular protrusions in ordered rows on a flat substrate each protrusion having a length (l) of 45 μm, a maximum width (w) of 9 μm, a height (h) of 15 μm, a base separation (bs) of 9 μm, a tip separation (ts) of 18 μm and a row separation (rs) of 3 μm. The second microstructured surface (A2 and B2) had an identical microstructure except all of the dimensions are twice the size, i.e. 2×. The third microstructured surface (A3 and B3) had an identical microstructure except all of the dimensions are 3×. The fourth microstructured surface (A5 and B5) had an identical microstructure except all of the dimensions are 5×.

Each substrate was tested with sand, dry soil (i.e. dry mud) and wet soil (i.e. wet mud). For the sand and dry soil, if any particles stuck to the surface, the surface was banged a few times to see if the particles dislodged and for the wet soil, if it stuck to the surface, a water wash (using a syringe) was used to see if it washed off easily.

Sand and Dry Mud Testing:

1) For all the hydrophobic (A samples), no mud/sand particles stuck to any of the surfaces including the reference surface.

2) This was not the case for the hydrophilic (B samples):

B0 (reference surface): mud and sand particles stuck to this surface.

B1 (1×): this structure performed better than B0; less particles stuck and when banged a few times, many of the particles dislodged.

B2 (2×): This performed better than B1 and B0 with regards dry mud, with no particles sticking to the surface. However, it performed worse than B1 and B0 on sand with more particles sticking to its surface.

B3 (3×): this performed better with mud than B1 and B0.

With regards sand, B3 performed better than all the other surfaces (but one stubborn sand particle stuck to surface).

B5 (5×): Some sand particles stuck to this surface but were easily dislodged upon tapping. No mud particles stuck to this surface and was found to be the best performer all round for the hydrophilic samples.

Wet Mud Testing:

1) For the hydrophobic (A samples), wet mud stuck only to the micro-structure-less reference sample (A0) but was easily washed off its surface. For all the other A surfaces, no wet mud stuck and so no wash was required.

2) For the hydrophilic (B samples), all performed poorly with wet mud easily sticking to all the surfaces but mud washing off each easily using water from a syringe lightly squirted onto each surface

These results are summarised in the below tables.

Hydrophobic structures (A)

| | Sand | Dry soil | Wet soil |
|---|---|---|---|
| Unstructured | ✓ | ✓ | X |
| (A0) | No particles | No particles | Wet mud stuck but was |
| | stuck | stuck | easily washed off |
| 1x | ✓ | ✓ | ✓ |
| (A1) | No particles | No particles | no wet mud stuck |
| | stuck | stuck | |
| 2x | ✓ | ✓ | ✓ |
| (A2) | No particles | No particles | no wet mud stuck |
| | stuck | stuck | |
| 3x | ✓ | ✓ | ✓ |
| (A3) | No particles | No particles | no wet mud stuck |
| | stuck | stuck | |
| 5x | ✓ | ✓ | ✓ |
| (A5) | No particles | No particles | no wet mud stuck |
| | stuck | stuck | |

Hydrophillic structures (B)

| | | Dry soil | Wet soil |
|---|---|---|---|
| | Sand | (i.e. dry mud) | (i.e. wet soil) |
| Unstructured | X | X | X |
| (B0) | particles stuck | Particles stuck | wet mud stuck |
| | | | but was washed |
| | | | off easily using |
| | | | water from a |
| | | | syringe lightly |
| | | | squirted onto |
| | | | each surface |
| 1x | ✓ | ✓ | X |
| (B1) | Fewer particles | Fewer particles | wet mud stuck |
| | stuck than | stuck than | but was washed |
| | B0 and many | B0 and many | off easily using |
| | dislodged when | dislodged when | water from a |
| | the structure was | the structure was | syringe lightly |
| | banged a few times | banged a few times | squirted onto |
| | | | each surface |
| 2x | X | ✓ | X |
| (B2) | performed worse | performed better | wet mud stuck |
| | than B1 and B0 on | than B1 and B0 | but was washed |
| | sand with more | with no particles | off easily using |
| | particles sticking | sticking to the | water from a |
| | to its surface | surface | syringe lightly |
| | | | squirted onto |
| | | | each surface |
| 3x | ✓ | ✓ | X |
| (B3) | performed better | (performed better | wet mud stuck |
| | than all the other | than B1 and B0 | but was washed |
| | surfaces (but one | with no particles | off easily using |
| | stubborn sand | sticking to the | water from a |
| | particle stuck | surface | syringe lightly |
| | to surface) | | squirted onto |
| | | | each surface |
| 5x | ✓ | ✓ | X |
| (B5) | Some sand particles | No mud particles | wet mud stuck |
| | stuck to this | stuck to this | but was washed |
| | surface but wer | surface | off easily using |
| | easily dislodged | | water from a |
| | upon tapping | | syringe lightly |
| | | | squirted onto |
| | | | each surface |

The samples were also tested with regard to their effect on water. When water droplets were dropped onto the hydrophobic samples (A samples), the droplet beads sat on the surfaces. However for the A0 sample (unstructured reference samples) the water spread a little and even though water ran off the surface easily, traces of a water trail could be seen. This was not the case for the other structured A samples on which the water drop spread less than the A0 sample and did not leave a water trail.

For the hydrophilic B samples, the water run-off was tested and with regards to the microstructured samples it was found that water ran-off much easier either when running down parallel to the direction of the protrusions but not across the structures (i.e. perpendicular to the longitudinal axis of the protrusions) whereby the water stuck and often did not move across the surface.

1-25. (canceled)

26. A surface microstructure, the surface microstructure comprising:
a surface; and
a plurality of protrusions on the surface,
wherein each of the protrusions has a width that changes along its length,
wherein the protrusions are all oriented in substantially the same direction; and
wherein the protrusions each have a length between 10 and 1000 μm and a maximum width between 5 and 100 μm.

27. The surface microstructure according to claim 26, wherein the surface microstructure has improved self-cleaning properties compared to the same surface without the protrusions.

28. The surface microstructure according to claim 26, wherein each protrusion is connected to the surface along its entire length.

29. The surface microstructure according to claim 26, wherein the protrusion decreases in width along its length to a point at one end of the protrusion, wherein each protrusion is triangular.

30. The surface microstructure according to claim 26, wherein the maximum width of each protrusion is between 9 to 45 μm, and/or the length of each protrusion is between 45 μm to 225 μm.

31. The surface microstructure according to claim 26, wherein the protrusions are all be substantially identical.

32. The surface microstructure according to claim 26, wherein the surface microstructure is hydrophobic.

33. The surface microstructure according to claim 26, wherein over 50% of the surface is covered by the protrusions.

34. The surface microstructure according to claim 26, wherein the surface microstructure is coated with a reflector so as to provide a structural colour to the surface microstructure.

35. The surface microstructure according to claim 26, wherein the surface is a fiber, and wherein the protrusions have been formed by cutting grooves into the surface of the fibre.

36. An article comprising the surface microstructure of claim 26.

37. The article according to claim 36, wherein the surface microstructure is a first surface microstructure provided on a first region of the article and wherein the article comprises a second region with a second surface microstructure, wherein the first and second microstructures have different properties.

38. A method of manufacturing a surface microstructure, the method comprising:
providing a surface; and
providing a plurality of protrusions on the surface,
wherein each of the protrusions has a width that changes along its length,
wherein the protrusions are all oriented in substantially the same direction; and
wherein the protrusions each have a length between 10 and 1000 μm and a maximum width between 5 and 100 μm.

39. The method according to claim 38, wherein the protrusions are formed by at least one of stamping, moulding, 3D-printing, or a self-assembly technique.

40. The method according to claim 39, wherein the self-assembly technique is self-assembly of the protrusions in a drying liquid, wherein the liquid is manipulated to self-form the protrusions by including structures into the liquid, and wherein each structure causes one protrusion.

41. The surface microstructure according to claim 26, wherein each protrusion has a length to maximum width ratio between 1:0.08 and 1:0.33.

42. The surface microstructure according to claim 26, wherein a height of each protrusion is between 15 and 75 μm.

43. The surface microstructure according to claim 26, wherein a distance between each protrusion at its base is substantially the same as a width of the protrusions and/or a distance between each protrusion at its tip end is between 1 and 200 μm.

44. The surface microstructure according to claim 26, wherein the protrusions are in rows, and wherein each row is separated by a gap between 1 and 100 μm.

45. The surface microstructure according to claim 26, wherein a material of the protrusions is different to that of the surface.
